(19) United States
(12) Patent Application Publication
(10) Pub. No.: US 2022/0392562 A1
(43) Pub. Date: Dec. 8, 2022

(54) AUTOMATICALLY SKIP BAD BLOCK IN CONTINUOUS READ OR SEQUENTIAL CACHE READ OPERATION

(71) Applicant: MACRONIX INTERNATIONAL CO., LTD., Hsinchu (TW)

(72) Inventors: Shuo-Nan HUNG, Hsinchu (TW); Chun-Lien SU, Taichung (TW)

(73) Assignee: MACRONIX INTERNATIONAL CO., LTD., HSINCHU (TW)

(21) Appl. No.: 17/341,821

(22) Filed: Jun. 8, 2021

(51) Int. Cl. G11C 29/44; G11C 29/18; G11C 29/00

(52) U.S. Cl. CPC G11C 29/4401; G11C 29/18; G11C 29/886; G11C 2029/1802; G11C 2029/4402

(57) ABSTRACT

The disclosed technology provides for automatically skipping bad block(s) in continuous read or sequential read operations in memory devices including NAND flash memory. Bad blocks can be skipped by analyzing block integrity during one at a time addressing of the blocks, or by skipping sets of consecutive bad blocks in a set of bad blocks using stored bad block information. Multiple sets of consecutive bad blocks can also be analyzed and skipped. A list of good blocks can be maintained, and only good blocks are used when performing a continuous cache read or sequential read operation. The list can be maintained in non-volatile memory enabling the device to load the block addresses upon power on startup. Additionally, a command to add additional blocks when received can implement adding new blocks to the list.

### BACKGROUND

### Field

The present invention relates to handling bad blocks during memory operations and specifically to mechanisms for automatically skipping bad block(s) in continuous read or sequential read operations in memory devices including NAND flash memory.

### Description of Related Art

Large-scale memory arrays, including large-scale NAND flash memory, may not be perfect, with specifications allowing on the order of 2% or more bad blocks in the array during the lifetime of the device. Bad blocks can cause issues for users in some situations.

Bad blocks are typically handled by causing the system to “skip the bad blocks”. However, handling bad blocks in certain memory operations such as in a sequential cache read or continuous read operation poses difficulties for the system because there is the need to change the block during the sequential or continuous operation. Performing the read operation on a good block and then restarting the operation for next good block can come at the cost of degraded system performance. Alternately, random reads under control of the host bring greater complexity to the interface. None of these techniques would be sufficiently robust in the event of a bad block in boot code area of the flash device. Thus, the typical operations do not suffice for bad blocks encountered during these types of operations, such as might be encountered on large-scale NAND flash memory devices.

It is desirable therefore to provide techniques for automatically skipping bad block(s) in continuous read or sequential read operations in memory devices including NAND flash memory.

### SUMMARY

The disclosed technology provides methods for automatically skipping bad block(s) in continuous read or sequential read operations in memory devices including NAND flash memory. In general, by way of overview and in implementations, bad blocks can be skipped by analyzing block integrity during one at a time addressing of the blocks, or by skipping sets of consecutive bad blocks in a set of bad blocks using stored bad block information. Multiple sets of consecutive bad blocks can also be analyzed and skipped. A list of good blocks can be maintained, and only good blocks are used when performing a continuous cache read or sequential read operation. The list can be maintained in non-volatile memory enabling the device to load the block addresses upon power on startup. Additionally, a command to add additional blocks when received can implement adding new blocks to the list.

In a representative implementation, a memory device, comprises a memory array. A data register is operatively coupled to the memory array. A cache is operatively coupled to the data register. An input/output interface is operatively coupled to the cache. It can facilitate exchanging data with at least a host. Bad block circuits identify bad blocks in the memory array. Also included is a controller responsive to commands and addresses received at the input/output interface, including logic circuits to control memory operations including: (i) an array read operation to output a stream of data segments from the memory array to the data register, and from the data register to the cache, and (ii) a cache read operation decoupled from the array read operation to output data from the cache to the input/output interface. The array read operation can also include generating a sequence of segment addresses to access the stream of data segments from the array, and can be responsive to the bad block circuits to skip bad blocks identified by the bad block circuits in the generation of the sequence of addresses.

In some implementations, logic circuitry checks a block in the array read operation and whenever a result of this checking a block in the array read operation indicates that the block in the array read operation is a bad block, an address to a next block is incremented; thereby skipping bad blocks one at a time.

In some implementations, logic circuitry compares a block in the array read operation to bad block information for a first bad block of a set of consecutive bad blocks and whenever a result of this comparing a block in the array read operation to bad block information for a first bad block of a set of consecutive bad blocks indicates that the block in the array read operation is a first bad block of consecutive blocks, an address of a next good block is obtained; thereby skipping remaining bad blocks in the set of consecutive bad blocks.

In some implementations, an address of a next good block is obtained from bad block list entries in a configuration settings data image.

In some implementations, the logic circuitry stores the configuration settings data image in the array.

In some implementations, bad block circuitry implements one or more bad block registers that receive one or more entries denoting bad blocks from the memory blocks storing the configuration settings data image.

In some implementations, the logic circuitry further implements analyzing bad block information during a power on operation and adds any bad block information that results from the analyzing as new bad block list entries in the configuration settings data image.

In some implementations, the logic circuitry further implements receiving an assign bad blocks command from a host and adds bad block information as a new bad block list entry in the configuration settings data image.

In some implementations, logic circuitry compares a block in the array read operation to bad block information for a first bad block of a group of N consecutive blocks contemporaneously and whenever a result of this comparing a block in the array read operation to bad block information for a first bad block of a group of N consecutive blocks contemporaneously indicates that the block in the array read operation is a first bad block of consecutive blocks, an address of a next good block is obtained; otherwise a counter is incremented, the next group is selected and the comparing can be performed on a next group of N consecutive blocks. Variously, N is determined by 2^{m}; wherein m is a selectable design criterion.

In some implementations, logic circuitry checks whether a block in the array read operation is from a different block from a previous array read operation, and whenever a result of this checking indicates that the block in the array read operation is from a different block, logic circuitry checks whether the block is a bad block.

In some implementations, bad block information stored in non-volatile storage is read into bad block registers during power on.

In some implementations, bad block registers store bad block information in control logic circuitry or a row decoder.

In another embodiment, a method of skipping bad blocks during a continuous read operation or a sequential read operation in a non-volatile memory is provided that includes responsive to commands and addresses received at an input/output interface of the non-volatile memory, performing operations of: (i) an array read operation, and (ii) a cache read operation decoupled from the array read operation. An array read operation can comprise performing: (a) outputting a stream of data segments from a memory array to a data register, and (b) outputting a stream of data segments from the data register to a cache. A cache read operation can comprise performing: outputting data from the cache to the input/output interface. The array read operation further includes: generating a sequence of segment addresses to access the stream of data segments output from the memory array; and responsive to indications from bad block circuits, skipping bad blocks identified by the bad block circuits in the generation of the sequence of addresses.

In some implementations, the method further includes analyzing bad block information during a power on operation; and responsively adding any bad block information that results from the analyzing as new bad block list entries in a bad blocks list.

In some implementations, the method further includes receiving an assign bad blocks command from a host; and responsively adding bad block information as a new bad block list entry in a bad block list.

Implementations of the disclosed technology can provide improved semiconductor device performance when used with continuous read or sequential read operations. Other aspects and advantages of the present invention can be seen on review of the drawings, the detailed description and the claims, which follow.

### BRIEF DESCRIPTION OF THE DRAWINGS

FIG. 1 is a simplified block diagram of an integrated circuit memory device suitable for embodying a mechanism for automatically skipping bad block(s) in continuous read or sequential read operations.

FIG. 2 is a flowchart illustrating a bad block assignment operation for assigning blocks to a configurable bad block list for an integrated circuit memory device like that of FIG. 1

FIG. 3A is a flowchart illustrating a read operation in which bad blocks are automatically skipped for an integrated circuit memory device like that of FIG. 1.

FIG. 3B is an example address definition 300B for use with flowchart 300A of FIG. 3A.

FIG. 4A is a state diagram illustrating example continuous or sequential read transactions for the integrated circuit memory device resulting from the bad block skipping operation in an integrated circuit memory device like that of FIG. 1.

FIG. 4B is a pipeline dataflow diagram for one embodiment of a page continuous read as described herein.

FIG. 4C is a second pipeline dataflow diagram for one embodiment of a page continuous read as described herein.

FIG. 5A is a flowchart illustrating a read operation in which groups of consecutive bad blocks are automatically skipped for an integrated circuit memory device like that of FIG. 1.

FIG. 5B is a flowchart illustrating an alternative read operation in which groups of consecutive bad blocks are automatically skipped for an integrated circuit memory device like that of FIG. 1.

FIG. 6A is a diagram illustrating example consecutive bad block information for an integrated circuit memory device implementing a continuous or sequential read transaction like that of FIG. 5A.

FIG. 6B is a diagram illustrating example consecutive bad block information for an integrated circuit memory device implementing a continuous or sequential read transaction like that of FIG. 5B.

FIG. 7 is a diagram illustrating a command structure for a representative “assign block jump” operation for the integrated circuit memory device like that of FIG. 1.

FIG. 8A is a flowchart illustrating a read operation in which groups of consecutive bad blocks are automatically skipped for an integrated circuit memory device like that of FIG. 1.

FIG. 8B is a flowchart illustrating a check bad blocks in a group of blocks during a read operation in which groups of consecutive bad blocks are automatically skipped for an integrated circuit memory device like that of FIG. 1.

FIG. 9 is a diagram illustrating example of detecting bad block information in N consecutive blocks for a continuous or sequential read transaction for the integrated circuit memory device like that of FIG. 1.

### DETAILED DESCRIPTION

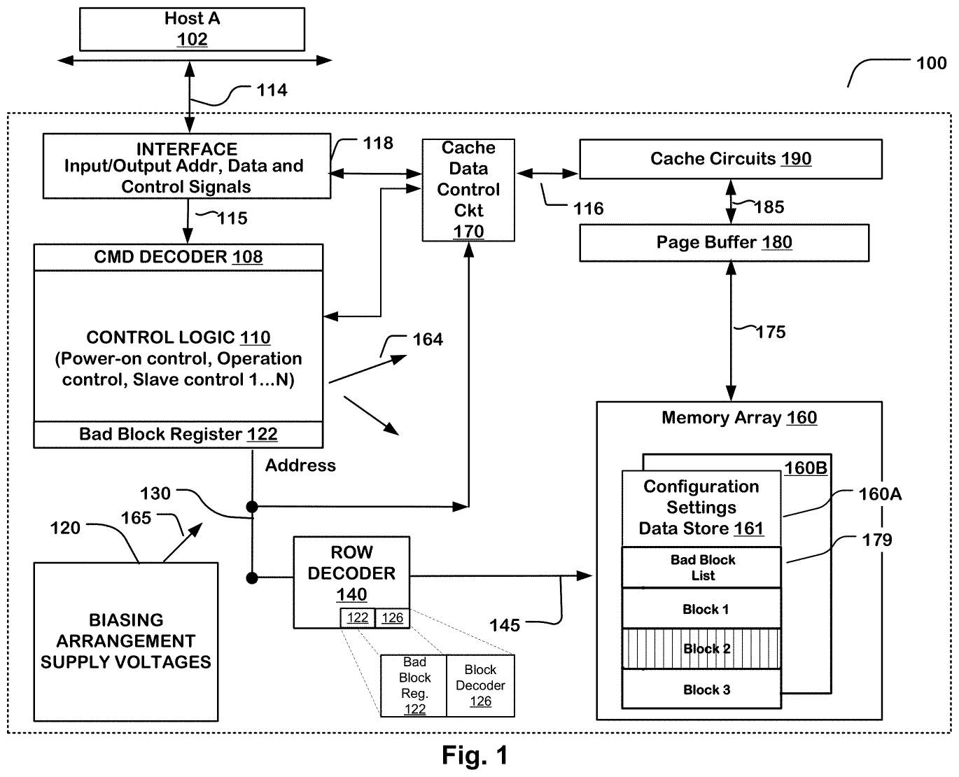

A detailed description of embodiments of the presently disclosed technology is provided with reference to the FIGS. 1-9.

Storage arrays of modern memory systems, such as for example NAND Flash, are may contain bad blocks, i.e., one or more blocks of defective storage locations, and the obligation to handle bad blocks falls on the user. The typical way for the system to handle the bad block is “skip the bad blocks”. However, handling the bad blocks in a sequential cache read operation or a continuous read operation is especially problematic for the system because there is a need to change the block during the sequential or continuous operation.

In general, by way of overview and in implementations, a non-volatile memory device is provided the capability to skip bad blocks when performing a continuous cache read or sequential read operation. Devices skip bad blocks by employing techniques herein to analyze block integrity during one block at a time addressing of the blocks, or by skipping sets of consecutive bad blocks in a set of bad blocks using stored bad block information. Multiple sets of consecutive bad blocks can also be analyzed and skipped. A list of good blocks can be maintained, and only good blocks are used. The list can be maintained in non-volatile memory enabling the device to load the block addresses upon power on startup. Additionally, a command to add additional blocks when received can implement adding new blocks to the list.

FIG. 1 is a simplified block diagram of a memory system including a NAND flash memory device implemented on an integrated circuit suitable for embodying a mechanism for automatically skipping bad block(s) in continuous read or sequential read operations as described herein.

In various embodiments, the memory device can be implemented on a single integrated circuit chip, on a multichip module, or on a plurality of chips configured as suits a particular need. In yet other embodiments contemplated herein, the memory device may have other types of non-volatile memory cells, including programmable resistance memory cells, such as metal oxide memory cells, magneto-resistive memory cells or phase change-based memory cells, and so on. This diagram is merely an example, which should not unduly limit the scope of the claims herein. One of ordinary skill in the art would recognize other variations, modifications, and alternatives.

Control logic circuits 110 with a command decoder 108, on the integrated circuit memory device 100, includes logic, such as a state machine, responsive to received commands to execute continuous read operations, including one or more of the operations described herein with reference to FIGS. 1-9. The control logic circuits 110 outputs control signals, represented by arrows on the diagram, and addresses on bus 130. The addresses applied on bus 130 can include for example outputs of an address counter in the control logic circuits 110, or addresses carried in received commands.

The memory array 160 can be a NAND flash memory in embodiments contemplated herein implemented using two-dimensional or three-dimensional array technology. The memory array 160 is arranged in an array including a plurality of blocks of memory cells. The blocks of memory cells include sets of memory cells that fall within a specified range of addresses in the memory array, and can be said to have block addresses. In some embodiments of flash memory, erase operations are executed on sectors in the memory array that can be partitioned electrically during the erase operation from other sectors. Blocks of memory cells can encompass a single sector, and thus may be referred to as an erase block. In other embodiments, blocks of memory cells implemented for the purposes of the present technology may include more than one sector, or other configurations of memory cells.

An input/output interface 118 is included in which addresses and data may be provided on shared lines in an address/data bus 114. Also, serial interfaces may be deployed.

A row decoder 140 is coupled to a plurality of word lines 145, arranged along rows in the memory array 160. Word line decoders are included in row decoder 140. A cache data control circuit/column decoder 170 is coupled to cache circuits 190 by a plurality of bit lines 116 to select the target data in the cache circuits 190 to output data read from or input data written to the memory array 160. Addresses are supplied on lines 130 from control logic circuits 110 implementing a command decoder 108 and controller modules, to cache data control circuit/column decoder 170 and to row decoder 140, which is coupled to memory array 160 by word lines 145.

Page buffer circuits 180 are coupled to a plurality of bit lines 175 arranged along columns in the memory array 160 for reading data from and writing data to the memory array 160. Page buffer circuits 180 are coupled by data lines 185 to the cache circuits 190, and can store pages of data. Bit lines 175 are coupled to the page buffer circuits 180, and to the memory array, and can comprise global bit lines (GBL) and local bit lines. Bit lines generally comprise conductors in higher patterned layers that can traverse a plurality of blocks or sectors of memory cells in an array, and connect to local bit lines in the blocks via select transistors. The local bit lines are connected to the memory cells for current flow to and from the bit lines, which in turn are connected to the bit lines 175 and data registers in page buffer circuits 180. In one implementation, the page buffer can be the same width as the memory array.

In a reading operation, data from the supplied from the array to the data registers in the page buffer circuits 180, and from the data registers via second data lines 185 to cache circuits 190, in this example, which are in turn coupled to input/output interface 118 via data path lines 116. Also, input data is applied in this example to the cache circuits 128 on lines 116 from the input/output interface 118, and to the page buffer circuits 180 on data lines 185, for use in support of program operations.

Input/output interface 118 provides communication paths for the data with destinations external to the memory device 100. Input/output data and control signals are moved via data lines 115 between the input/output interface 118 and the control logic circuits 110 on the memory device 100. In some embodiments, other data sources internal or external to the memory device 100, can be included such as a general-purpose processor or special purpose application circuitry, or a combination of modules providing system-on-a-chip functionality supported by the memory array 160.

In the example shown in FIG. 1, control logic circuits 110 include control modules implementing a bias arrangement state machine, or machines, which controls, or control, the application of supply voltages generated or provided through the voltage supply or supplies in block 120, such as read, erase, verify and program voltages including pre-charge voltages, for a set of selectable program and read operations. Supply voltages are applied to memory device 100, as shown by arrow 165. Control circuit signals are distributed to circuits in memory device 100, as shown by arrows 164.

The control logic circuits 110 are coupled to the cache circuits 190 and the memory array 160 and other elements of the integrated circuit as needed.

The control logic circuits 110 can include modules implemented using special-purpose logic circuitry including state machines, as known in the art. In alternative embodiments, the control logic circuits 110 can include modules implemented using a general-purpose processor, which can be implemented on the same integrated circuit, which execute a computer program to control the operations of the memory device 100. In yet other embodiments, a combination of special-purpose logic circuitry and a general-purpose processor can be utilized for implementation of modules in control logic circuits 110.

The control logic circuits 110 implement a controller that is responsive to the commands and addresses received at the input/output interface, including logic circuits to control memory operations including i) an array read operation to output a stream of data segments from the memory array to the data register, and from the data register to the cache, and ii) a cache read operation decoupled from the array read operation to output data from the cache to the input/output interface. The cache read operation can be controlled by the host by issuing cache read commands and controlling the read clock, as data becomes available in the cache as resources in the host become available to receive the data, while the array read operation can execute autonomously under control of internal logic after it is initiated by a continuous or sequential read command. See, co-pending and commonly owned, U.S. patent application Ser. No. 17/061,451, entitled CONTINUOUS READ WITH MULTIPLE READ COMMANDS, filed 10 Jan. 2020, which is incorporated by reference as if fully set forth herein.

The autonomous array read operation includes generating a sequence of segment (e.g. page) addresses to access the stream of data segments from the array. The autonomous array read as described herein is responsive to the bad block register circuits 122 in the generation of the sequence of addresses to skip bad blocks identified by the bad block circuits in the generation of the sequence of addresses.

As described herein, control logic circuits 110 and/or block decoder 126 of row decoder 140 include field configurable bad block register circuits 122. The field configurable bad block register circuits 122 can include circuits or memory identifying a list 179 of bad blocks (e.g., block 1, block 2, block 3) in configuration blocks (e.g., 161) in the array 160. The field configurable bad block register circuits 122 can comprise circuit elements such as lookup tables, configuration registers, content addressable memory, comparators, and enable and disable circuits and the like. The field configurable bad block register circuits 122 can be configurable by writing data from the configuration blocks to the lookup tables, configuration registers or content addressable memory.

A bad block list 179 can be used to configure the bad block register circuits with the list or the mapping or both, by transferring the information to the circuits upon power on of the device 100 or receipt of an assign bad block function command by the device 100. Also, the bad block list 179 may be part of the bad block register circuits. The bad block list 179 can be stored in nonvolatile memory on the device, such as within a prespecified region of the flash memory array 160. In other embodiments, the bad block list 179 can be stored in a configuration register that can be written at least once located on other parts of the memory device 100. This configuration register can comprise flash memory cells, or other types of nonvolatile memory cells as suits a particular embodiment.

The field configurable bad block register circuits can respond to or read the bad block list 179 in response to a block register event. A block register event can be a reset event, such as may occur on a chip power-on initialization operation, receipt of a reset command, and receiving an assign bad block function command from the user to identify additional reserved blocks or additional bad blocks for inclusion into the list, or initiated by control logic circuits 110 upon completion of an operation in which a bad block is detected in order to write an identifier of a bad block, or other type of event, such as expiration of a timer, or a reset signal from a host. In some implementations the block register event can occur automatically in execution of an operation by the controller on the device, without user intervention. The information from the bad block list 179 can be applied to configure the circuitry to map continuous read or sequential cache read commands that skip over bad blocks to the next available good blocks identified by the information in the bad block list 179.

The flash memory array 160 can comprise floating gate memory cells or dielectric charge trapping memory cells configured to store multiple bits per cell, by the establishment of multiple program levels that correspond to amounts of charge stored, which in turn establish memory cell threshold voltages VT. The technology can be used with single-bit-per-cell flash memory, and with other multiple-bit-per-cell (multiple-level cells storing more than one bit per cell (e.g., MLC, TLC or XLC)) and single-bit-per-cell memory technologies (single-level cells (SLC)). In other examples, the memory cells may comprise programmable resistance memory cells, phase change memory cells, and other types of nonvolatile and volatile memory cell technologies.

In the illustrated example, the host 102 is coupled to the data and address lines 114 on the memory device 100, as well as other control terminals not shown, such as chip select terminals and so on, and can provide commands or instructions to the memory device 100 in the field. In some examples, the host 102 can be coupled to the memory device using a serial bus technology, using shared address and data lines. The host 102 can comprise a general-purpose processor, a special purpose processor, a processor configured as a memory controller, or other processor that uses the memory device 100. All or part of the host 102 can be implemented on the same integrated circuit as the memory.

The host 102 can include a file system or file systems that store, retrieve, and update data stored in the memory based on requests from an application program or multiple application programs. In general, the host 102 can also include programs that perform memory management functions and other functions that can produce status information for data stored in the memory, including information marking data invalid as a result of such functions. Such functions can include, for example, wear leveling, bad block recovery, power loss recovery, garbage collection, error correction, and so on. Also, the host 102 can include application programs, file systems, flash translation layer programs and other components that can produce status information for data stored in the memory, including information marking data invalid as a result of such functions.

For the purposes of this description, the circuitry is “configurable in the field” or “responsive to commands in the field,” because it is designed to be configured after manufacture by logic on the chip, or by a customer or user. Examples of configuration in the field include writing bad block data to the bad block information table in response detection of bad blocks by error detection logic, writing data to the bad block information table in response to user commands originating in a host system identifying bad blocks, writing data in response to user commands originating in a host system identifying reserved blocks to a bad block list 179, and resetting and re-creating bad block lists in the control logic 110.

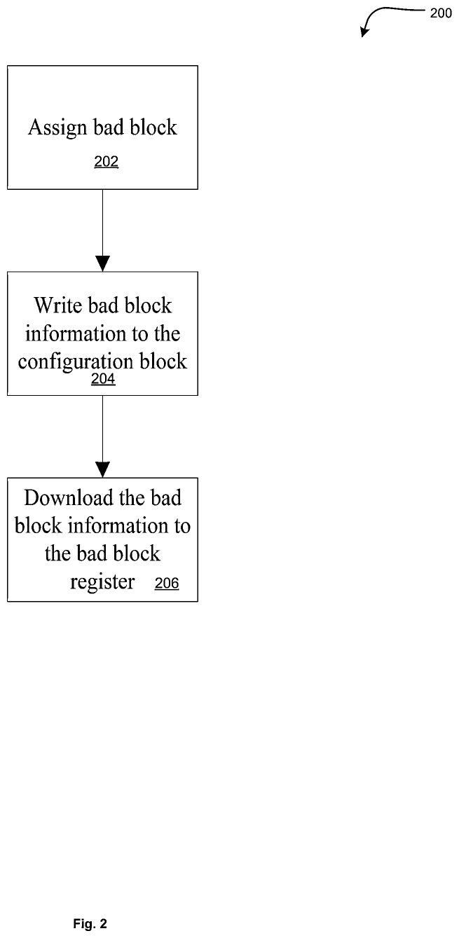

Having described an example architecture for implementing automatically skipping bad block(s) in continuous read or sequential read operations in a storage memory, next examples of update/change bad block information and skipping block operations conducted upon continuous read or sequential read operations, using the configuration logic mechanisms like that of FIG. 1, will be described with reference to state diagrams and flowcharts of FIGS. 2-9.

### Process for Assigning Blocks to a Bad Block List

Now with reference to flowchart 200 of FIG. 2, an example of a bad block assignment operation for assigning blocks to a configurable bad block list will be described. In one implementation, blocks are assigned initially before shipment, by a user after receiving the device or combinations thereof and stored in a non-volatile block of the array 160. FIG. 2 is a flowchart illustrating a bad block assignment operation for assigning blocks to a configurable bad block list for an integrated circuit memory device like that of FIG. 1.

In an action 202, the block is assigned to the bad block list. In implementations, blocks can be assigned by a vender of the memory device 100 that builds the bad block list. Initial bad block list can be built before shipment of the device. Additional blocks may be added to the bad block list in the event of failure of a write (program or erase) operation during test for example. In some implementations, the device 100 provides an assign bad block function for the user to assign blocks to the bad block list. In some implementations, both vendor and user can assign blocks to the bad block list (e.g. Initial bad block list before shipment by vendor) and additional blocks assigned by the user (e.g. Running bad blocks list during operation).

In an action 204, the bad block list information is written to the configuration block 179 in memory array 160 of device 100.

In an action 206, the bad block information is downloaded from the configuration block 179 to the bad block register circuits 122. After a write operation the host can confirm that the bad block information is successfully written to the configuration block.

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

### Process for Skipping Bad Blocks Automatically

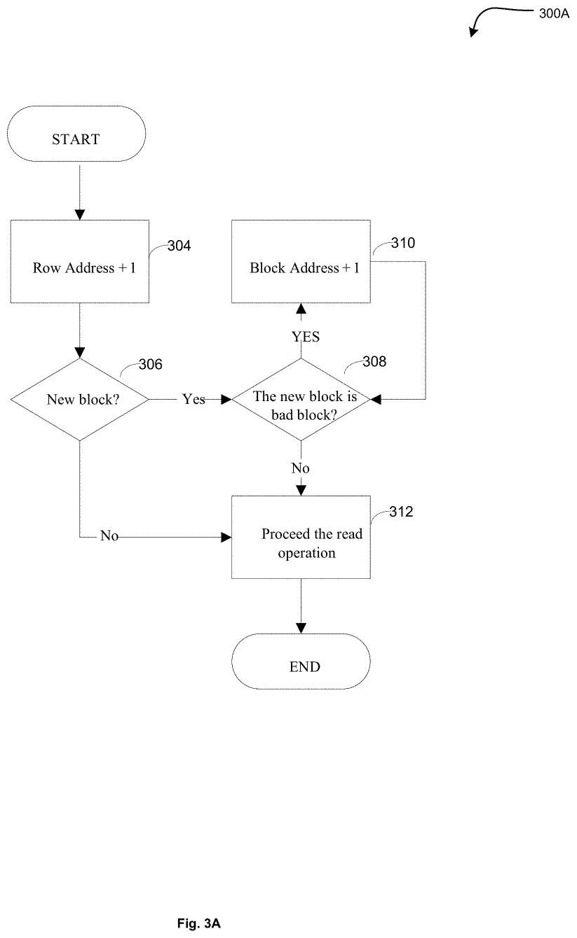

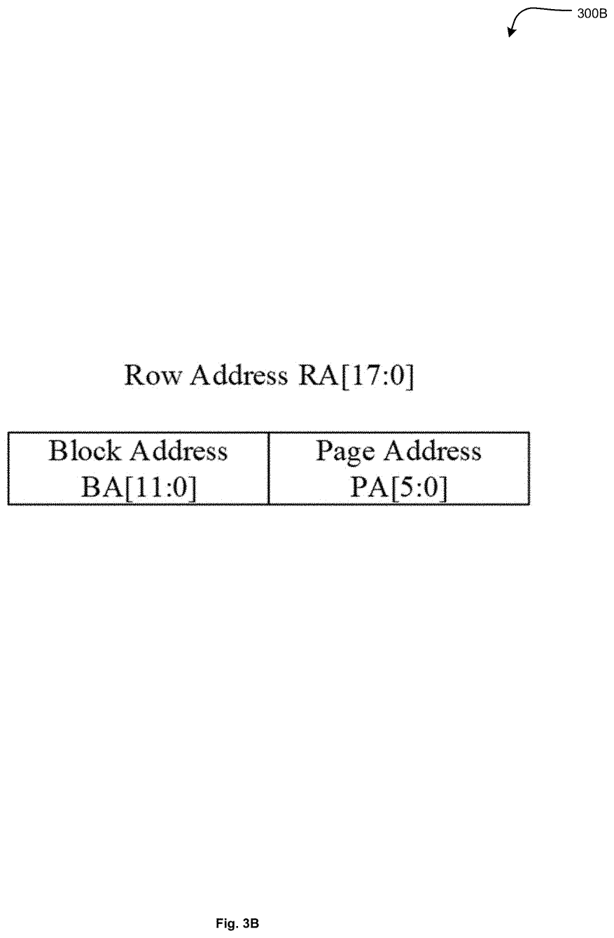

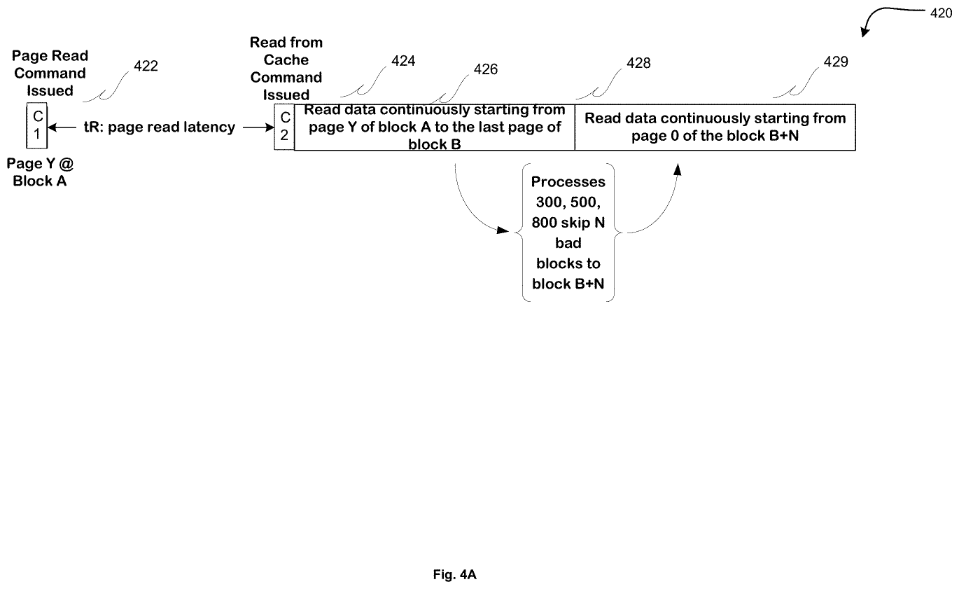

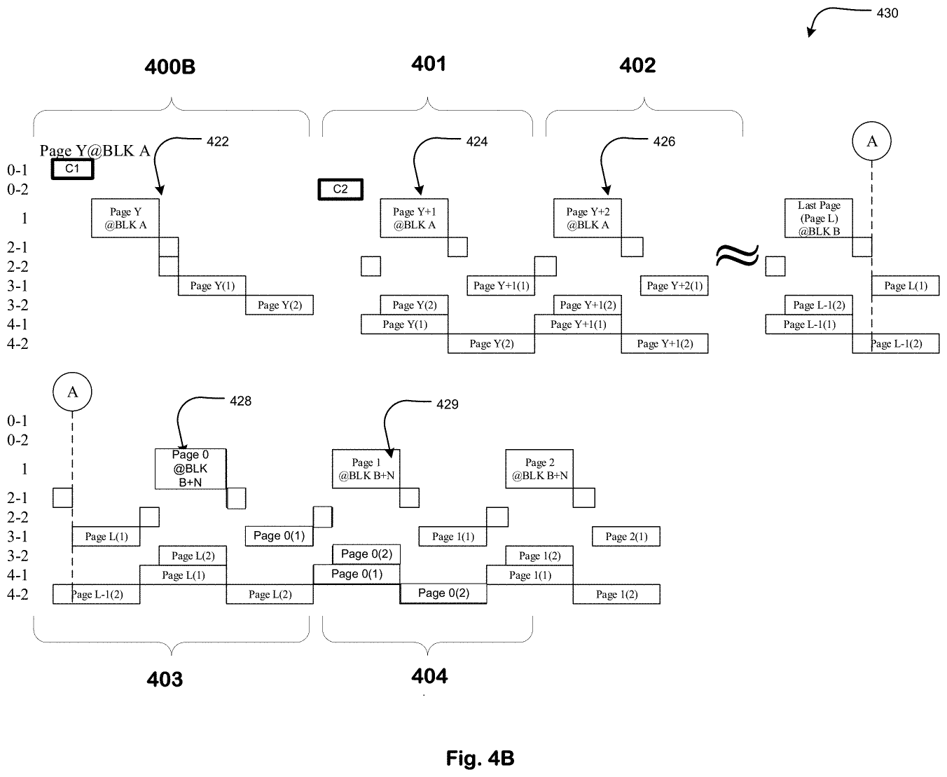

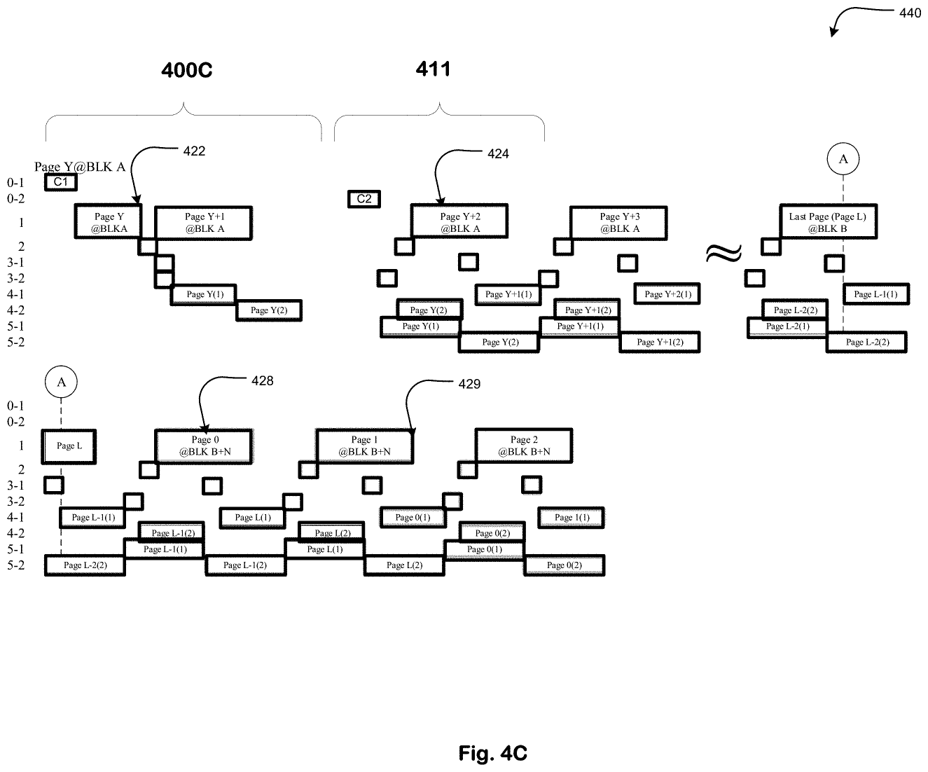

Now with reference to flowchart 300A of FIG. 3A and state diagram 420 of FIG. 4A, and pipeline flow diagrams 400B and 400C of FIGS. 4B and 4C respectively, an example of processing implementing automatically skipping bad blocks in a read operation will be described. FIG. 3A is a flowchart illustrating a read operation in which bad blocks are automatically skipped during internal operation to read the next page for an integrated circuit memory device like that of FIG. 1 and FIG. 4A is a state diagram illustrating example continuous or sequential read transactions for the integrated circuit memory device resulting from the bad block skipping operation like that of FIG. 3A. A representative process for skipping bad blocks during sequential or continuous data reads will now be described.

In FIG. 3A, a read (also referred to herein as an array read) operation is initiated to obtain the next sequential page Y from memory into the Page buffer circuits 180. The read operation of flowchart 300A can be initiated as part of processing a page read command (C1) or a read from cache command (C2) of FIG. 4A as a portion of a sequential read or continuous read command issued by the host 102 to a memory device 100. With reference to FIGS. 4A, 4B, and 4C, bad blocks may be skipped in any or both of states 422, 424, in which a page read command (C1), or a read from cache command (C2), respectively, commences reading the page Y of block A.

In an action 304, a row address is incremented. This prepares the device 100 to read the next Sequential page, Y+1 from memory array 160 into Page buffer circuits 180 in a subsequent page read.

In an action 306, the device 100 checks to see if a block boundary is crossed. There are many different kinds of design implementations for determining whether a block boundary is crossed. For example, by comparing the block address to a previous address to see if the block is different. Another way, with reference to an address definition 300B shown in FIG. 3B, is to check whether the page address is 0; this will be a new block if the page address=0. If the block of the new page is different from the block of the last page, then control passes to action 308, otherwise, control passes to an action 312.

In actions 308 and 310, that together implement a mechanism for stepping through blocks searching for the next good block, the new block is checked whether the new block is a bad block by checking the address of the new block against the bad block list 179. If the new block is a bad block, then in action 310, the block address is incremented, and control passes again to action 310 to check whether the next new block is a bad block. Actions 308 and 310 thus increment through bad blocks in the bad block list 179 until a good next block (B+N) is found. Then control passes to action 312. With reference to FIGS. 4A, 4B and 4C, FIGS. 4A and 4B show a state 424 in which N blocks have been skipped by operation of actions 308 and 310, enabling the read operation to continue reading data continuously staring from page 0 of the block B+N in state 428, the first non-bad block detected by action 308. With continuing reference to FIG. 4A and with reference to FIG. 4C, bad blocks can also be skipped in a state 422 of the read operation. Some implementations will skip bad blocks in one state of states 422 and 424, some implementations will skip bad blocks in another of the states 422, 424 and some implementations will skip bad blocks in both states 422, 424.

In action 312 the read operation proceeds to reading data from the next good block B+N. In a first example, in which blocks are skipped in processing a read from cache command in a state 424 of FIG. 4A, continued processing of the read in action 312 is illustrated by a flow 430 depicted in FIG. 4B. FIG. 4B illustrates data flow for a processing pipeline implementing skipping bad blocks in a context of a continuous or sequential read. In the diagram, the horizontal axis represents time, each vertical level corresponds to a particular data movement as follows:
0-1: receive page read command C1 for a new page.
0-2: receive read from cache intra-stream command C2 to read the data.
1: move the page data and ECCs from the memory array to the page buffer (both halves).
2-1: move the data from the first half of the page buffer to buffer BUF_A.
2-2 move the data from the second half of the page buffer to buffer BUF_B.
3-1: apply ECC logic for error detection and correction in buffer BUF_A.
3-2: apply ECC logic for error detection and correction in buffer BUF_B.
4-1: move the data from buffer BUF_A to the data path in the I/O interface.
4-2: move the data from buffer BUF_B to the data path in the I/O interface.

A first command C1 is received at the beginning at level 0-1 providing the beginning address of page Y. Proceeding diagonally down to level 4-2 as indicated by the elements within interval 400B for page Y, the data of page Y is loaded into the page buffer at level 1 (422). From the page buffer, a first half of the page is loaded into buffer BUF_A at level 2-1. Also, at a later time (or simultaneously) a second half of the page is loaded into buffer BUF_B at level 2-2. At level 3-1, while the first half of page Y is in buffer BUF_A, ECC circuitry is exercised over the ECC chunk or chunks in the first half of the page. Later, at level 3-2, while the second half of page Y is in buffer BUF_B, the ECC is exercised over the ECC chunk or chunks in the second half of the page. Finally, at level 4-1, the first half of page Y is provided to the I/O interface to be provided as output when the cache read command C2 is received at level 0-2. At level 4-2, the second half of page is provided to the I/O interface continuous with the first half. As described herein, actions 302-310 can skip any bad blocks during the intra-stream command C2 processing (state 424 of FIG. 4A) (read from cache) can carry an address of a next page in the continuous read sequence. A sequence of continuous reads (intervals 401, 402, 403, 404 . . . ) can be executed in this sequence, responding to a series of commands to output a stream of pages in which bad blocks are automatically skipped. With renewed reference to FIG. 3A, in state 424 of FIGS. 4A and 4B, actions 308, 310 skip N bad blocks enabling reading data starting from page 0 of the next good block B+N in state 428 (and continuing on to a subsequent page 1 of next good block B+N in state 429). The procedure shown in FIG. 4B is an example of the controller responding to a series of commands to output a stream of pages. The controller responds to the first command to initiate a continuous page read operation, to transfer a first addressed page in the stream from the memory array to the page buffer, and move the first addressed page through the data path circuits to the interface. The controller responds to a first intra-stream command received after a read latency and including a next page address to (to enable) output of the first addressed page from the interface in I/O data units.

In a second example, in which blocks are skipped in processing a read from cache command in a state 422 of FIG. 4A and FIG. 4C, continued processing of the read in action 312 is illustrated by a flow 440 depicted in FIG. 4C. FIG. 4C illustrates data flow for a processing pipeline implementing skipping bad blocks in a context of a continuous or sequential read. In the diagram, the horizontal axis represents time, each vertical level corresponds to a particular data movement as follows:
0-1: receive first page read command C1 for a first page.
0-2: receive first intra-stream page read command C2 for a second page.
1: move the page data and ECCs from the memory array to the page buffer (both halves).
2: move the page data from the page buffer to buffer 2_BUF_A and buffer 2_BUF_B.
3-1: move the data from the first half of the page in buffer 2_BUF_A to buffer 3 BUF_A.
3-2 move the data from the second half of the page in buffer 2_BUF_B to buffer 3 BUF_B.
4-1: apply ECC logic for error detection and correction in buffer 3 BUF_A.
4-2: apply ECC logic for error detection and correction in buffer 3 BUF_B.
5-1: move the data from buffer 3 BUF_A to the data path in the I/O interface.
5-2: move the data from buffer 3 BUF_B to the data path in the I/O interface.

The end of sequence command is not illustrated in FIG. 4C for clarity's sake. See, co-pending and commonly owned, U.S. patent application Ser. No. 16/533,463, entitled FAST PAGE CONTINUOUS READ, filed 6 Aug. 2019, which is incorporated by reference as if fully set forth herein.

In FIG. 4C, a first continuous read command C1 is received in interval 400C at the level 0-1 identifying a first page, page Y, for the sequence. Proceeding diagonally down to level 5-2 for page Y, the data of page Y is loaded into the page buffer at level 1. From the page buffer, the data of page Y is loaded into the first buffer level, including buffer 2_BUF_A and buffer 2_BUF_B in a single transfer at level 2 of the figure in this embodiment before data from the next page Y+1 is loaded to the page buffer. After the data of page Y is moved out of the page buffer, into the data path circuits, the data of page Y+1 is moved into the page buffer.

Subsequently, at level 3-1, the data from buffer 2_BUF_A is transferred to buffer 3 BUF_A in the second buffer level. Thereafter, or simultaneously, at level 3-2, the data from buffer 2_BUF_B is transferred to buffer 3 BUF_B in the third buffer level.

In level 4-1, the ECC circuitry operates on the ECC chunks of page Yin buffer 3 BUF_A. At level 4-2, the ECC circuitry operates on the ECC chunks of page Y in buffer 3 BUF_B.

Thereafter at level 5-1, the data of page Yin buffer 3 BUF_A is available at the interface.

At level 5-2, the data of page Y in buffer 3 BUF_B is available at the interface.

After the first continuous read command C1 in interval 400C, a second continuous read command C2 is received in interval 411 after tR, while the data of page Y is output (level 5-1) at the interface aligned with C2.

As illustrated in FIG. 4C, the data of page Y+1 traverses the data path circuits so it is available after operation of the ECC circuits at the I/O interface in a manner that is contiguous with the end of page Y. The procedure continues in a pipelined manner through the data path circuits as illustrated in FIG. 4C until the continuous read operation is terminated.

With renewed reference to FIG. 3A, in state 422 of FIGS. 4A and 4C, actions 308, 310 skip N bad blocks to start enabling reading data starting from page 0 of the next good block B+N in state 428 (and continuing on to a subsequent page 1 of next good block B+N in state 429).

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

Noteworthy is that in certain implementations, read performance of a memory chip may be degraded in instances where there are many consecutive bad blocks in the array. This can arise because the memory chip will take extra time to locate the next good block if there are too many consecutive bad blocks. Next we turn to another implementation that addresses this issue with reference to FIGS. 4A and 4B, 5A and 5B, and 6A and 6B.

### Consecutive Bad Blocks

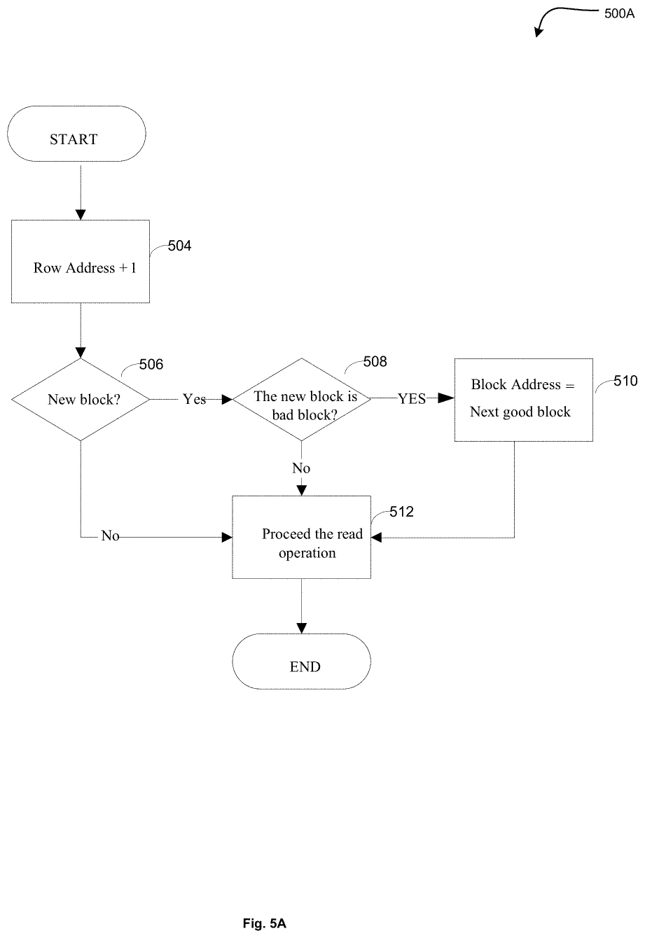

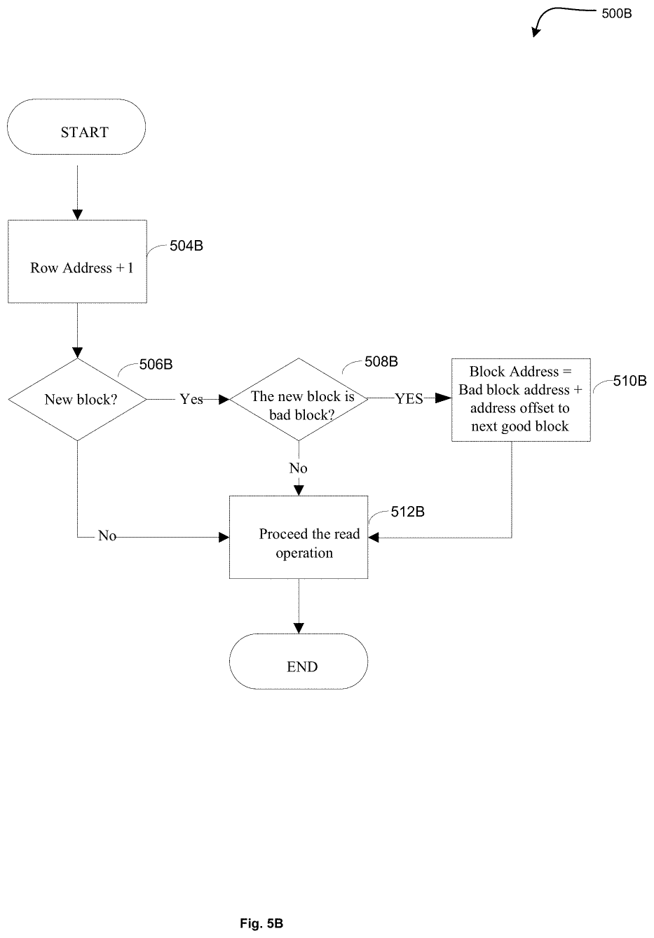

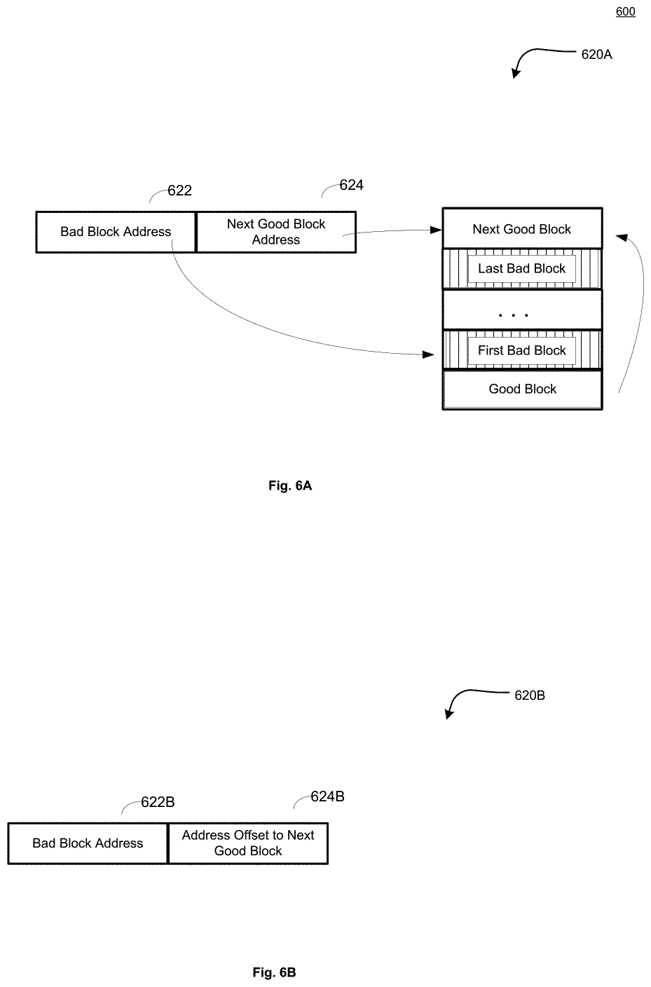

Sometimes bad blocks that are consecutive can occur. Next we describe implementations of our technology address this scenario, in which the chip first checks whether a new block is the first bad block in a set of consecutive bad blocks and continues to the next good block if the new block is the first bad block in the set of consecutive bad blocks. Now with reference to flowchart 500A of FIG. 5A state diagram 420 of FIG. 4A, pipeline flow diagrams 400B and 400C of FIGS. 4B and 4C respectively, and a diagram 600 of consecutive bad block information 620A of FIG. 6A, an example of processing implementing automatically skipping groups of consecutive bad blocks in a read operation will be described. FIG. 5A is a flowchart illustrating a read operation in which groups of consecutive bad blocks are automatically skipped for an integrated circuit memory device like that of FIG. 1 and FIG. 6A is a diagram illustrating example bad block information in a continuous or sequential read transaction for the integrated circuit memory device like that of FIG. 1. A representative process for skipping consecutive bad blocks during sequential or continuous data reads will now be described.

In FIG. 5A, a read operation is initiated to obtain the next sequential page from memory into the Page buffer circuits 180. The read operation of flowchart 500A can be initiated as part of processing a page read command (C1) or a read from cache command (C2) of FIG. 4A as a portion of a sequential read or continuous read command issued by the host 102 to a memory device 100. With returning reference to FIGS. 4A, 4B, and 4C, bad blocks may be skipped in any or both of states 422, 424, in which a page read command (C1), or a read from cache command (C2), respectively, commences reading the page Y of block A.

In an action 504, a row address is incremented. This prepares the device 100 to read the next Sequential page, Y+1 from memory array 160 into Page buffer circuits 180 in a subsequent page read.

In an action 506, the device 100 checks to see if a block boundary is crossed. There are many different kinds of design implementations for determining whether a block boundary is crossed. For example, by comparing the block address to a previous address to see if the block is different. Another way, with reference to an address definition 300B shown in FIG. 3B, is to check whether the page address is 0; this will be a new block if the page address=0. If the block of the new page is different from the block of the last page, then control passes to action 508, otherwise, control passes to an action 512.

In action 508 device 100 determines based upon stored consecutive bad block information 620A of FIG. 6A that the block is the first bad block, indicated by bad block address 622 of the consecutive bad block information 620A, of a group of consecutive bad blocks. If the block is the first bad block of a set of consecutive bad blocks, then control passes to action 510.

In an action 510, the next block address is set to the next good block address 624 of the consecutive bad block information 620A. The read flow then passes to action 512, in which the device 100 will go to the next good block if it is the first bad block in the consecutive bad blocks.

With renewed reference to FIGS. 4A, 4B and 4C, FIGS. 4A and 4B show a state 424 in which N blocks have been skipped by operation of actions 508 and 510, enabling the read operation to continue reading data continuously staring from page 0 of the block B+N in state 428, the first non-bad block detected by action 508. With continuing reference to FIG. 4A and with reference to FIG. 4C, bad blocks can also be skipped in a state 422 of the read operation. Some implementations will skip bad blocks in one state of states 422 and 424, some implementations will skip bad blocks in another of the states 422, 424 and some implementations will skip bad blocks in both states 422, 424.

In an action 512, the read operation proceeds to reading data from the next good block B+N in a manner analogous to the actions described above with reference to FIGS. 4A, 4B, and 4C.

In an alternative method, the number of registers needed to store bad block information can be reduced. Now with reference to flowchart 500B of FIG. 5B and a diagram 600 of consecutive bad block information 620B of FIG. 6B, we next describe an implementation in which the bad block register includes the bad block address 622B and the address offset 624B to the next good block. Because the size of the number needed to represent address offset 624B to the next good block will be significantly smaller in comparison to the size of a number needed to represent the next good block address, storing the offset instead of storing the next address requires less register space. Example of processing implementing automatically skipping groups of consecutive bad blocks in a read operation using offset 624B is depicted by flowchart 500B illustrated in FIG. 5B will now be described.

In FIG. 5B, actions 504B, 506B, 508B, and 512B essentially mirror their like numbered counterparts in FIG. 5A. In action 510B, however, the block address for the next block to read from is obtained by adding the bad block address 622B and the address offset 624B.

### Creating Consecutive Bad Block Information

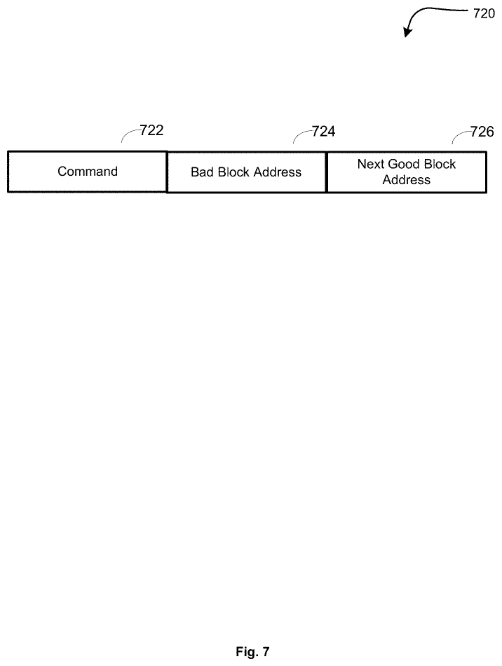

Consecutive bad blocks information 620A, 620B can be created in one or more ways in various memory device implementations. In one implementation, consecutive bad blocks information is derived from analysis of the bad block information by the memory chip during the power on operation and the assign bad block operation. Alternatively, and with reference to FIG. 7, consecutive bad block information is constructed with assistance of the host 102 through an “assign block jump” function. In this implementation, the host 102 issues a command to provide bad block information to the device. Commands can have the command format 720 illustrated by FIG. 7, for example, in which a command 722 provides the bad block address 724 and the next good block address 726 to the device 100. This information will be written to the bad block list 179 of the configuration settings data store 161 and downloaded to the control logic circuits 110 during power on operation, by an assign bad block operation and an assign block jump operation, respectively.

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

Having looked at a memory device that implements skipping consecutive blocks, we next turn to another chip implementation that embodies technology to perform multiple consecutive bad blocks detection, thereby reducing block detection time and enabling implementations to provide improved read performance with reference to FIGS. 4A and 4B, 8A and 8B, and 9.

### Multiple Consecutive Bad Blocks

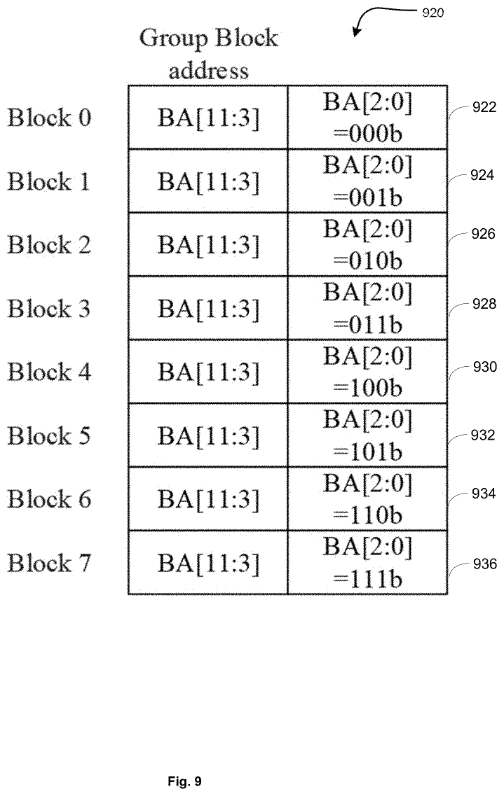

In another embodiment, the chip first checks whether a new block is the first bad block in N sets of consecutive bad blocks contemporaneously. The typical N consecutive blocks case is that 2^{m} blocks. The higher blocks address is the same and lower m block address are different for 2^{m} blocks. Implementation specifics determine appropriate values of N or m, essentially a design point. It is a tradeoff between the die size and the performance; a larger m will take more die size for simultaneous bad block checks, so in a presently preferred implementation m≤3 is employed. In some implementations, a block repair scheme can be used to avoid too many consecutive bad blocks as needed or desired. The following example with reference to FIG. 9 illustrates an example of consecutive bad block information 920 having eight consecutive blocks 922, 924, 926, 928, 930, 932, 934, and 936 in FIG. 9.

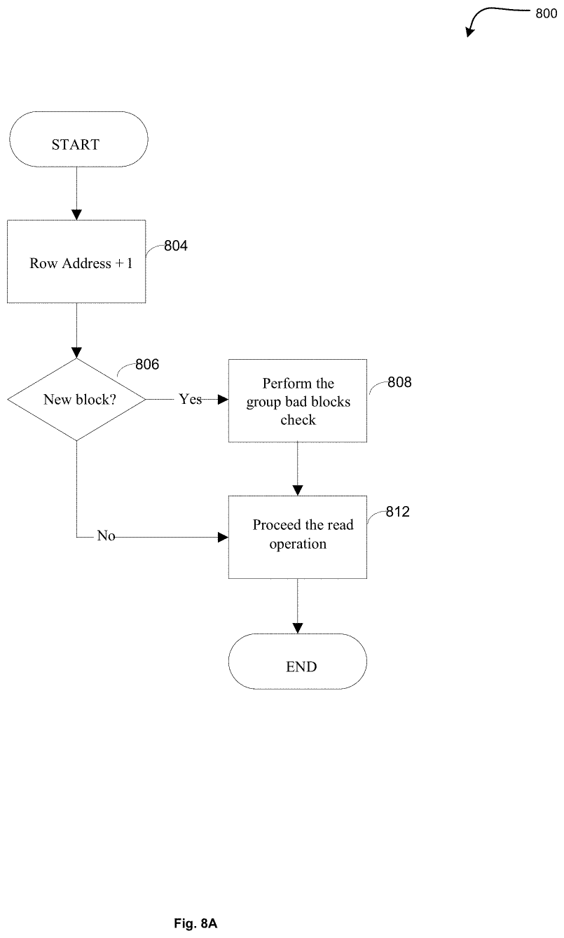

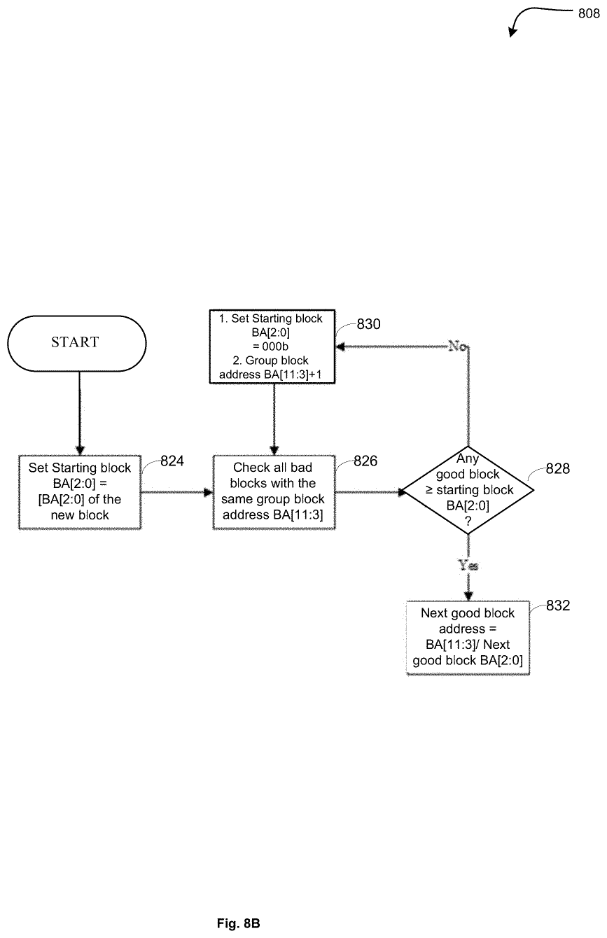

Now with reference to flowchart 800 of FIG. 8A and state diagram 420 of FIG. 4A, and pipeline flow diagrams 400B and 400C of FIGS. 4B and 4C respectively, and a diagram 900 of consecutive bad block information 920 of FIG. 9, an example of processing implementing automatically skipping groups of consecutive bad blocks in a read operation will be described. FIG. 8A is a flowchart illustrating a read operation in which groups of consecutive bad blocks are automatically skipped for an integrated circuit memory device like that of FIG. 1 and FIG. 9 is a diagram illustrating example of detecting bad block information in N consecutive blocks for a continuous or sequential read transaction for the integrated circuit memory device like that of FIG. 1. A representative process for skipping consecutive bad blocks during sequential or continuous data reads will now be described.

In FIG. 8A, a read operation is initiated to obtain the next sequential page from memory into the Page buffer circuits 180. The read operation of flowchart 800A can be initiated as part of processing a page read command (C1) or a read from cache command (C2) of FIG. 4A as a portion of a sequential read or continuous read command issued by the host 102 to a memory device 100. With renewed reference to FIGS. 4A, 4B, and 4C, bad blocks may be skipped in any or both of states 422, 424. in which page read command (C1), or a read from cache command (C2), respectively, commences reading the page Y of block A.

In an action 804, a row address is incremented. This prepares the device 100 to read the next Sequential page, Y+1 from memory 160 into Page buffer 180 in a subsequent page read.

In an action 806, the device 100 checks to see if a block boundary is crossed. There are many different kinds of design implementations for determining whether a block boundary is crossed. For example, by comparing the block address to a previous address to see if the block is different. Another way, with reference to an address definition 300B shown in FIG. 3B, is to check whether the page address is 0; this will be a new block if the page address=0. If the block of the new page is different from the block of the last page, then control passes to action 808 to perform group bad blocks checking; otherwise, control passes to an action 812.

Now with reference to FIG. 8B and FIG. 9, processing for performing a group blocks check of action 808 is depicted with greater detail by the flowchart shown in FIG. 8B in which device 100 detects N consecutive blocks (922, 924, 926, 928, 930, 932, 934, and 936) contemporaneously based upon bad block list 179 that stores consecutive bad block information 920 of FIG. 9. In FIG. 9, if the Block address is BA[11:0] and each group of consecutive bad block information 920 is 8 blocks, blocks (e.g., 922, 924, 926, 928, 930, 932, 934, and 936) then each group will be the 8 blocks with the same BA[11:3]. In this way, the bad block check for the N consecutive blocks is only to check all bad blocks with the same group BA[11:3] using processing such as that of the flowchart shown in FIG. 8B:

In FIG. 8B, bad block checking for the representative group BA[11:3] is performed.

In action 824, checking starts by setting Starting block BA[2:0]=BA[2:0] of the new block.

In action 826, all bad blocks with the same group block address BA[11:3] are checked.

In action 828, control logic determines whether any good blocks>=Starting block BA[2:0]? If the answer is no, then control flows to action 830 to reset and pick the next group. Otherwise, control flows to action 832.

In action 830, the next group of blocks is checked, by setting Starting block BA[2:0]=000b, incrementing the group block address BA[11:3], and passing control back to action 826 to again check for all bad blocks with the same (next) group block address BA[11:3].

In action 832, the next good block address is found to be BA[11:3] and the next good block is found to be BA[2:0].

With renewed reference to FIGS. 4A, 4B and 4C, FIGS. 4A and 4B show a state 424 in which N blocks have been skipped by operation of action 808, enabling the read operation to continue reading data continuously staring from page 0 of the block B+N in state 428, the first non-bad block detected by action 808. With continuing reference to FIG. 4A and with reference to FIG. 4C, bad blocks can also be skipped in a state 422 of the read operation. Some implementations will skip bad blocks in one state of states 422 and 424, some implementations will skip bad blocks in another of the states 422, 424 and some implementations will skip bad blocks in both states 422, 424.

In an action 812, the read operation proceeds to reading data from the next good block B+N in a manner analogous to the actions described above with reference to FIGS. 4A, 4B, and 4C.

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

Any data structures and code described or referenced above are stored according to many implementations on a computer-readable storage medium, which may be any device or medium that can store code and/or data for use by a computer system. This includes, but is not limited to, volatile memory, non-volatile memory, application-specific integrated circuits (ASICs), field-programmable gate arrays (FPGAs), magnetic and optical storage devices such as disk drives, magnetic tape, CDs (compact discs), DVDs (digital versatile discs or digital video discs), or other media capable of storing computer-readable media now known or later developed.

A byte is a basic storage unit used in many integrated circuit logic and memory circuits, and comprises of eight bits. Basic storage unit can have other sizes, including for example one bit, two bits, four bits, 16 bits and so on. Thus, the description of a memory device set out above, and in other examples described herein utilizing the term byte, applies generally to circuits using different sizes of storage units, as would be described by replacing the term byte or set of bytes, with storage unit or set of storage units. Also, in some embodiments different sizes of storage units can be used in a single command sequence, such as one or more four bit storage units combined with eight bit storage units.

### Particular Implementations

A device having a controller logic circuitry, and a method responsive to (i) an array read operation to output a stream of data segments from the memory array to a data register, and from the data register to a cache, and (ii) a cache read operation decoupled from the array read operation to output data from the cache, are described herein.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation, thereby enabling skipping of blocks indicated as bad.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation, thereby enabling skipping of blocks indicated as bad during a read from cache operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation by the logic circuitry checking a block in the array read operation, and whenever a result of the check indicates that the block in the array read operation is a bad block, an address is incremented to a next block, thereby enabling skipping of blocks indicated as bad during a read from cache operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation by logic circuitry comparing a block in the array read operation to bad block information for a first bad block of a set of consecutive bad blocks, and whenever a result of the compare indicates that the block in the array read operation is a first bad block of consecutive blocks, an address of a next good block is obtained, thereby enabling skipping of blocks indicated as bad during a read from cache operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation by logic circuitry comparing a block in the array read operation to bad block information for a first bad block of a set of consecutive bad blocks, and whenever a result of the compare indicates that the block in the array read operation is a first bad block of consecutive blocks, an address of a next good block is obtained, thereby enabling skipping of blocks indicated as bad during a read from cache operation, and the logic circuitry further implements analyzing bad block information during a power on operation and responsively adding any bad block information that results from the analyzing as new bad block list entries in a configuration settings data image.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation by logic circuitry comparing a block in the array read operation to bad block information for a first bad block of a set of consecutive bad blocks, and whenever a result of the compare indicates that the block in the array read operation is a first bad block of consecutive blocks, an address of a next good block is obtained, thereby enabling skipping of blocks indicated as bad during a read from cache operation, and logic circuitry further implements receiving an assign bad blocks command from a host and responsively adding bad block information as a new bad block list entry in a configuration settings data image.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation, the logic circuitry compares a block in the array read operation to bad block information for a first bad block of a group of N consecutive blocks substantially contemporaneously, and whenever a result of the compare indicates that the block in the array read operation is a first bad block of consecutive blocks, an address of a next good block is obtained; otherwise incrementing the group and comparing to a next group of N consecutive blocks, thereby enabling skipping of blocks indicated as bad during a read from cache operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation, the logic circuitry compares a block in the array read operation to bad block information for a first bad block of a group of N consecutive blocks substantially contemporaneously, and whenever a result of the compare indicates that the block in the array read operation is a first bad block of consecutive blocks, an address of a next good block is obtained; otherwise incrementing the group and comparing to a next group of N consecutive blocks, wherein N is determined by 2^{m}; wherein m is an integer such as 1, 2, 3, and so on, thereby enabling skipping of blocks indicated as bad during a read from cache operation.

A device having a controller logic circuitry, and a method responsive to (i) an array read operation to output a stream of data segments from the memory array to a data register, and from the data register to a cache, and (ii) a cache read operation decoupled from the array read operation to output data from the cache are described, including responsively examining integrity of blocks in a set of blocks read in the array read operation, the logic circuitry checks a block in the array read operation is from a different block from a previous array read operation, and whenever a result of the check indicates that the block in the array read operation is from a different block, the logic circuitry checks whether the block is a bad block, thereby enabling skipping of blocks indicated as bad during a read from cache operation.

A number of flowcharts illustrating logic executed by a memory controller or by memory device are described herein. The logic can be implemented using processors programmed using computer programs stored in memory accessible to the computer systems and executable by the processors, by dedicated logic hardware, including field programmable integrated circuits, and by combinations of dedicated logic hardware and computer programs. With all flowcharts herein, it will be appreciated that many of the steps can be combined, performed in parallel or performed in a different sequence without affecting the functions achieved. In some cases, as the reader will appreciate, a re-arrangement of steps will achieve the same results only if certain other changes are made as well. In other cases, as the reader will appreciate, a re-arrangement of steps will achieve the same results only if certain conditions are satisfied. Furthermore, it will be appreciated that the flow charts herein show only steps that are pertinent to an understanding of the invention, and it will be understood that numerous additional steps for accomplishing other functions can be performed before, after and between those shown.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
a memory array;
a data register operatively coupled to the memory array;
a cache operatively coupled to the data register;
an input/output interface operatively coupled to the cache;
bad block circuits to identify bad blocks in the memory array; and
a controller responsive to the commands and addresses received at the input/output interface, including logic circuits to control memory operations including i) an array read operation to output a stream of data segments from the memory array to the data register, and from the data register to the cache, and ii) a cache read operation decoupled from the array read operation to output data from the cache to the input/output interface;
wherein the array read operation includes generating a sequence of segment addresses to access the stream of data segments from the array, and is responsive to the bad block circuits to skip bad blocks identified by the bad block circuits in the generation of the sequence of addresses.

2. The memory device of claim 1, further including logic circuits to control:
checking a block in the array read operation, and whenever a result of the check indicates that the block in the array read operation is a bad block, incrementing an address to a next block; thereby skipping bad blocks one at a time.

3. The memory device of claim 1, further including logic circuits to control:
comparing a block in the array read operation to bad block information for a first bad block of a set of consecutive bad blocks, and
whenever a result of comparing indicates that the block in the array read operation is a first bad block of consecutive blocks, obtaining an address of a next good block; thereby skipping remaining bad blocks in the set of consecutive bad blocks.

4. The memory device of claim 3, wherein obtaining an address of a next good block includes:
obtaining an address of a next good block from bad block list entries in a configuration settings data image.

5. The memory device of claim 4, further including logic circuits storing the configuration settings data image in the array.

6. The memory device of claim 5, wherein bad block circuitry implements one or more bad block registers that receive one or more entries denoting bad blocks.

7. The memory device of claim 1, further including logic circuits to control:
analyzing bad block information during a power on operation and responsively adding any bad block information that results from the analyzing as new bad block list entries in a configuration settings data image.

8. The memory device of claim 1, further including logic circuits to control:
responsive to an assign bad blocks command from a host, adding bad block information as a new bad block list entry in a configuration settings data image.

9. The memory device of claim 1, further including logic circuits to control:
comparing a block in the array read operation to bad block information for a first bad block of a group of N consecutive blocks substantially contemporaneously; and
whenever a result of comparing indicates that the block in the array read operation is a first bad block of consecutive blocks, an address of a next good block is obtained; otherwise incrementing the group and comparing to a next group of N consecutive blocks.

10. The memory device of claim 9, wherein N is determined by 2^{m}; wherein m is integer value.

11. The memory device of claim 1, further including logic circuits to control:
checking a block in the array read operation is from a different block from a previous array read operation; and
whenever a result of the check indicates that the block in the array read operation is from a different block, checking whether the block is a bad block.

12. The memory device of claim 1, wherein bad block information stored in non-volatile storage is read into bad block registers during power on.

13. The memory device of claim 1, wherein bad block registers store bad block information in one selected from a control logic circuitry and a row decoder.

14. A method of skipping bad blocks during a continuous read operation or a sequential read operation in a non-volatile memory, the method comprising:
responsive to commands and addresses received at an input/output interface of the non-volatile memory, performing operations of:
(i) an array read operation, comprising:
a. outputting a stream of data segments from a memory array to a data register, and
b. outputting a stream of data segments from the data register to a cache, and
(ii) a cache read operation decoupled from the array read operation, comprising:
a. outputting data from the cache to the input/output interface; and
wherein the array read operation further includes:
generating a sequence of segment addresses to access the stream of data segments output from the memory array; and
responsive to indications from bad block circuits, skipping bad blocks identified by the bad block circuits in the generation of the sequence of addresses.

15. The method of claim 14, further including:
analyzing bad block information during a power on operation; and
responsively adding any bad block information that results from the analyzing as new bad block list entries in a bad blocks list.

16. The method of claim 15, further including:
receiving an assign bad blocks command from a host; and
responsively adding bad block information as a new bad block list entry in a bad block list.

17. The method of claim 14, wherein skipping bad blocks identified by the bad block circuits further comprises:
checking a block in the array read operation, and whenever a result of the check indicates that the block in the array read operation is a bad block, incrementing an address to a next block; thereby skipping bad blocks one at a time.

18. The method of claim 14, wherein skipping bad blocks identified by the bad block circuits further comprises:
comparing a block in the array read operation to bad block information for a first bad block of a set of consecutive bad blocks, and
whenever a result of comparing indicates that the block in the array read operation is a first bad block of consecutive blocks, obtaining an address of a next good block; thereby skipping remaining bad blocks in the set of consecutive bad blocks.

19. The method of claim 18, wherein obtaining an address further comprises:
obtaining an address of a next good block from bad block list entries in a configuration settings data image.

20. The method of claim 14, wherein skipping bad blocks identified by the bad block circuits further comprises:
comparing a block in the array read operation to bad block information for a first bad block of a group of N consecutive blocks substantially contemporaneously; and
whenever a result of comparing indicates that the block in the array read operation is a first bad block of consecutive blocks, an address of a next good block is obtained; otherwise incrementing the group and comparing to a next group of N consecutive blocks.
